(19) United States
(12) Patent Application Publication
(10) Pub. No.: US 2026/0341325 A1
(43) Pub. Date: Oct. 29, 2026

(54) MEMORY DEVICE WITH READ REFERENCE SIGNAL GENERATION

(71) Applicant: Commissariat à l'Energie Atomique et aux Energies Alternatives, Paris (FR)

(72) Inventors: Sébastien RICAVY, GRENOBLE (FR); Mathieu FAYE, GRENOBLE (FR); Clément CHEUNG, GRENOBLE (FR); Anass SAMIR, GRENOBLE (FR)

(21) Appl. No.: 19/658,520

(22) Filed: Apr. 25, 2026

(30) Foreign Application Priority Data
Apr. 28, 2025 (FR) 2504478

(51) Int. Cl. G11C 11/22

(52) U.S. Cl. CPC G11C 11/2273; G11C 11/221; G11C 11/2259

(57) ABSTRACT

A memory device (100) comprises an array (102) of memory elements (104) each comprising a transistor (106) and a ferroelectric capacitor (108); read reference elements (114), integrated into the array, each comprising a transistor (116); a reference capacitor (122) external to the array and coupled to a bit line (118) and/or a plate line (120) of the read reference elements; a pulse generator (124) whose an output is coupled to plate lines (112) of the memory elements and to the plate line of the read reference elements; and a differential sense amplifier (126) comprising a first input (128) coupled to bit lines (110) of the memory elements and a second input (130) coupled to the bit line of the read reference elements.

### TECHNICAL FIELD

The present disclosure generally relates to the field of memory devices with capacitive non-volatile memory elements of the FeRAM-type.

### BACKGROUND ART

In a memory device comprising an array of FeRAM-type capacitive memory elements, a reading of the states, or data, stored in these elements can be implemented by generating a read reference signal, for example a voltage, that is compared with a read signal whose value depends on the state stored in the memory element being read. The result of this comparison makes it possible to determine whether the value of the read signal being read corresponds to a state “1” or “0”. The value of the read reference signal must be as close as possible to the average value between that of a read signal obtained when the stored state corresponds to a state “1” and that of a read signal obtained when the stored state corresponds to a state “0”. The circuit generating the read reference signal plays an important role because its characteristics directly impact the performance of the memory device in terms of functionality, efficiency, speed, occupied surface area, etc.

The document WO 2022/072584 A1 proposes a circuit for generating a read reference voltage whose value is selected from several possible values, depending on the location of the memory element being read within the memory element array. The read reference voltage generation circuit comprises several sets of capacitors enabling the generation of different reference voltage values.

The solution proposed in this document has several drawbacks. First of all, because the read reference voltage generation circuit is a circuit external to the memory element array, its components are not subject to the same variations (temperature, voltage, etc.) as the memory elements. In addition, this solution does not allow to take into account the differences in variation related to the spatial position of the memory elements in the array. The read reference is therefore not structurally adjusted to current/voltage variations sensitive to the spatial position of the memory elements in the array. Moreover, such a read reference voltage generation circuit requires to implement a significant calibration phase to determine the different read reference voltage values.

The document U.S. Pat. No. 6,501,674 B2 proposes a read reference voltage generation circuit comprising a “dummy column” of memory elements, called reference memory elements, i.e. memory elements dedicated to generating the read reference voltage, which are similar to the memory elements used to store useful data but are not used to store useful data like the other memory elements in the array.

This solution also has disadvantages. Actually, the ferroelectric capacitors of the reference memory elements are sensitive to the local variability within the array, but also to the “imprinting” phenomenon, that corresponds to the difficulty of writing a state in a ferroelectric capacitor that has long stored a state opposite to the one to be written, and to the fatigue phenomenon whose consequence is that the more the number of write cycles in a ferroelectric capacitor increases, the more the value written in it is reduced. This causes a divergence in the behavior of the reference memory elements compared to the other memory elements in the array.

An alternative solution to using a read reference signal is to perform a differential reading of the memory elements. In such a configuration, each piece of data is stored in two separate memory elements in which complementary states are written. However, this solution has the major disadvantage of having a cost in terms of very large semiconductor surface area since it requires twice as much memory surface area, for a given storage capacity, as the devices that store each piece of data in a single memory element.

### SUMMARY OF INVENTION

There is a need to provide a memory device that does not have at least some of the disadvantages of the existing solutions.

To this end, a memory device is provided, comprising at least:
an array of memory elements in which each memory element comprises at least one transistor and at least one ferroelectric capacitor;
read reference elements, integrated into the array of memory elements, each comprising at least one transistor;
at least one reference capacitor external to the array of memory elements and coupled to a bit line and/or a plate line of the read reference elements;
a pulse generator whose at least one output is coupled to plate lines of the memory elements and to the plate line of the read reference elements;
a differential sense amplifier comprising a first input coupled to bit lines of the memory elements and a second input coupled to the bit line of the read reference elements.

According to a particular embodiment, said at least one reference capacitor comprises at least two portions of electrically conductive material spaced apart from each other by one or more non-ferroelectric materials.

According to a particular embodiment, said at least one reference capacitor is of the Metal-Insulator-Metal (MIM) or Metal-Oxide-Metal (MOM) type, or based on polysilicon, or of the Metal-Oxide-Semiconductor (MOS) type.

According to a particular embodiment, the read reference elements form a column of read reference elements coupled to the memory elements such that word lines are each coupled to gates of the transistors of the memory elements of a same row of the array and to a gate of the transistor of one of the read reference elements.

According to a particular embodiment, the second input of the differential sense amplifier is coupled to the bit line of the read reference elements through said at least one reference capacitor, and/or the output of the pulse generator is coupled to the plate line of the read reference elements through said at least one reference capacitor.

According to a particular embodiment, the memory device further comprises at least one multiplexer of the lines of the memory elements configured to couple the first input of the differential sense amplifier to at least one of the bit lines of the memory elements, and to couple the output of the pulse generator to one of the plate lines of the memory elements.

According to a particular embodiment, the memory device further comprises at least one multiplexer of the lines of the read reference elements configured to couple the second input of the differential sense amplifier to the bit line of the read reference elements, and to couple the output of the pulse generator to the plate line of the read reference elements.

According to a particular embodiment, the memory device further comprises at least one differential multiplexer configured to couple the first and second inputs of the differential sense amplifier to the multiplexer of the lines of the memory elements and to the multiplexer of the lines of the read reference elements.

According to a particular embodiment, the memory device further comprises at least:
a first differential multiplexer configured to couple the first input of the differential sense amplifier to the bit line coupled to the memory element being read or to a complementary bit line coupled to the memory element being read, and
a second differential multiplexer configured to couple the second input of the differential sense amplifier to the complementary bit line coupled to the memory element being read or to the bit line of the read reference elements.

According to a particular embodiment, the reference capacitor has a variable value.

According to a particular embodiment, the reference capacitor comprises a plurality of switches and a plurality of fixed value capacitors each coupled to one of the switches configured to connect or not connect one of the fixed value capacitors to conduction electrodes of the reference capacitor.

According to a particular embodiment, the fixed value capacitors have values different from one another.

According to a particular embodiment, the memory device further comprises a control circuit configured to control the switches according to a target value of the reference capacitor.

According to a particular embodiment, each of the memory elements is of the 1T1C type.

According to a particular embodiment, the memory device further comprises an additional capacitor coupled in parallel to the bit line of the read reference elements.

### BRIEF DESCRIPTION OF DRAWINGS

The foregoing characteristics and advantages, as well as others, will be explained in detail in the following description of particular embodiments made on a non-limiting basis, in connection with the appended Figures, among which:

FIG. 1 schematically illustrates an example of a memory device according to a first embodiment;

FIG. 2 schematically illustrates an example of a reference capacitor of a memory device according to a particular embodiment;

FIG. 3 schematically illustrates examples of signals obtained in a memory device according to the first embodiment;

FIG. 4 schematically illustrates an example embodiment of a part of the memory device according to the first embodiment;

FIG. 5 schematically illustrates an example of a memory device according to a second embodiment;

FIG. 6 schematically illustrates examples of signals obtained in a memory device according to the second embodiment; and

FIG. 7 schematically illustrates an example of a memory device according to a variant of the first embodiment.

### DESCRIPTION OF EMBODIMENTS

The same elements have been designated by the same references in the various Figures. In particular, structural and/or functional elements common to the various embodiments may have the same references and may have identical structural, dimensional and material properties. On the Figures, in order to facilitate their reading, the different elements are not represented at the same scale compared to each other.

For the sake of clarity, only the steps and elements useful for understanding the described embodiments have been illustrated and are detailed.

Unless otherwise specified, when reference is made to two elements connected to each other, this means directly connected without any intermediate elements other than conductors, and when reference is made to two elements linked or coupled to each other, this means that these two elements may be connected or linked via one or more other elements. Moreover, the terms “coupled”, “linked” and “connected” are used here to refer to electrical couplings, or links, or connections.

In the following description, when reference is made to absolute position qualifiers, such as the terms “front”, “rear”, “top”, “bottom”, “left”, “right”, etc., or to relative qualifiers such as the terms “above”, “below”, “upper”, “lower,” etc., or to orientation qualifiers such as the terms “horizontal”, “vertical”, etc., reference is made, unless otherwise specified, to the orientation of the Figures. However, these terms do not presume either the actual position or the actual orientation of the device when in use.

Unless otherwise specified, the terms “about”, “approximatively”, “substantially” and “of the order of” mean within 10%, preferably within 5%.

Similarly, unless otherwise indicated, the indicated ranges of values include the limits of those ranges.

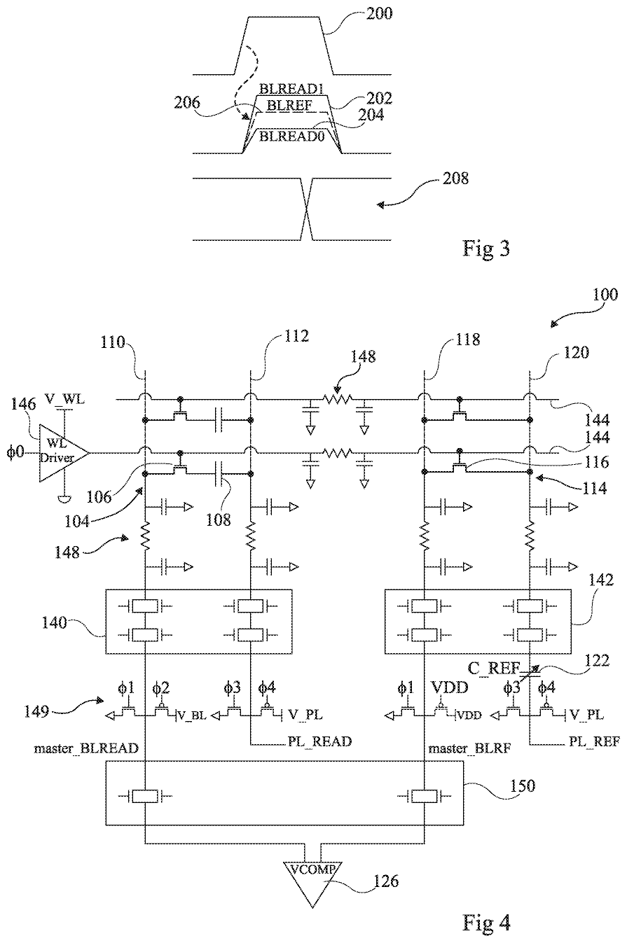

Moreover, the signals of FIGS. 3 and 6 are illustrated schematically and not to scale in relation to each other, both in terms of amplitude and of duration of the different parts of these signals.

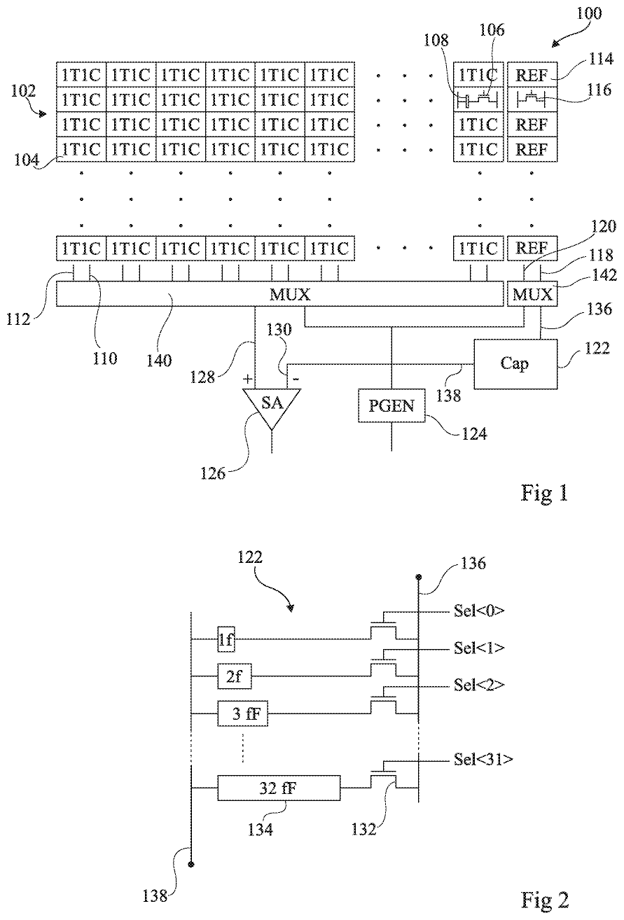

An example of a memory device 100 according to a first embodiment is described below in connection with FIG. 1.

The memory device 100 comprises at least one array 102 of memory elements 104. Each memory element 104 comprises at least one transistor 106 and at least one ferroelectric capacitor 108. The array 102 comprises N rows or lines and M columns of memory elements 104, where N and M correspond to integers, M being, for example, between 8 and 128, and N being, for example, between 16 and 1024. For example, M is equal to 32, which allows each line of memory elements 104 in the array 102 to form a 32-bit word.

In the described embodiment, each of the memory elements 104 is of the 1T1C type and therefore comprises a single transistor 106 coupled to a single ferroelectric capacitor 108. For example, each memory element 104 comprises a transistor 106 and a single ferroelectric capacitor 108 electrically coupled in series with each other. For example, the transistor 106 corresponds to a MOSFET transistor (“Metal-Oxide-Semiconductor Field-Effect Transistor”). As a variant, other types of memory elements 104 are possible.

In the described embodiment, the memory device 100 also comprises N word lines, each coupled to the gate of the transistor 106 of each memory element 104 of a same line of the array 102. The word lines, which are not visible in FIG. 1, are used to select the line of the array 102 in which an operation (read, write or erase) is to be performed, for example by setting in the on state transistors 106 of the memory elements 104 in that line. Although not illustrated in FIG. 1, the memory device 100 also comprises a word line control circuit, or “WL driver”, which applies the desired control voltages to the various word lines of the memory device 100.

Each of the transistors 106 comprises two conduction electrodes, one corresponding to the source electrode and the other corresponding to the drain electrode. In the described embodiment, the memory device 100 also comprises M bit lines 110, each coupled to one of the two conduction electrodes of the transistor 106 of each memory element 104 in a same column of the array 102. The bit lines 110 allow, in particular, during an operation for reading a memory element 104, to transmit a read signal delivered by the memory element 104 being read and whose value is representative of the state stored in the memory element 104 being read.

In each of the memory elements 104, the other of the two conduction electrodes of the transistor 106 is coupled to one of the two electrodes of the ferroelectric capacitor 108 of said memory element 104. In the described embodiment, the memory device 100 further comprises M plate lines 112, each coupled to the other of the two electrodes of the ferroelectric capacitor 108 of each memory element 104 of a same column of the array 102. The plate lines 112 allow, in particular, during an operation for reading a memory element 104, to apply, to the ferroelectric capacitors 108 of the memory elements 104 of the column to which the read memory element 104 belongs, a read pulse triggering the sending, by the memory element 104 being read, of the read signal on the bit line 110 to which the memory element 104 being read is coupled.

As a variant, each of the memory elements 104 may comprise other electronic components and/or have an arrangement of its electronic components different from that above described. In addition, the array 102 may comprise elements additional to those above described, and/or may have an organization of the memory elements 104 different from that previously described.

The memory device 100 further comprises read reference elements 114, integrated into the array 102 of memory elements 104, each comprising at least one transistor 116. In the described example embodiment, the transistors 116 are similar in terms of geometry, materials and electrical characteristics to the transistors 106 and are therefore, in this example, of the MOSFET type.

Moreover, in the here described example embodiment, the read reference elements 114 are arranged to form a column of elements coupled to the memory elements 104, for example at the end of the line as illustrated for the example of FIG. 1. Each of the word lines of the array 102 is coupled to the gates of the transistors 106 of the memory elements 104 of a same line of the array 102 and also to the gate of the transistor 116 of the read reference element 114 associated with this line of memory elements 104. As a variant, the arrangement of the column of read reference elements 114 may be different from that illustrated in FIG. 1, for example between two columns of memory elements 104 or at the beginning of a line.

In the described example embodiment, in each of the read reference elements 114, one of the two conduction electrodes of the transistor 116 is coupled to a bit line 118 of the read reference elements 114, this bit line 118 being coupled to all the read reference elements 114 because they all belong to a same column. The bit line 118 allows, in particular, during an operation for reading a memory element 104, to transmit a reference signal, for example a voltage, obtained from one of the read reference elements 114. Moreover, in each of the read reference elements 114, the other of the two conduction electrodes of the transistor 116 is coupled to a plate line 120 of the read reference elements 114, this plate line 120 being coupled to all the read reference elements 114 because they all belong to a same column. The plate line 120 allows, in particular, during an operation for reading a memory element 104, to apply a read pulse to the read reference element 114 belonging to the same line as the memory element 104 to be read, for example the same read pulse as that sent to the memory element 104 being read. Thus, the reference transistors 116 are connected between the reference bit line 118 and the reference plate line 120.

As a variant, the read reference elements 114 may comprise electronic components different from those of the above described example.

The memory device 100 further comprises at least one reference capacitor 122 external to the array 102 and coupled to the bit line 118 and/or the plate line 120 of the read reference elements 114.

The memory device 100 further comprises at least one pulse generator 124 whose at least one output is coupled to the plate lines 112 of the memory elements 104 and to the plate line 120 of the read reference elements 114.

The memory device 100 also comprises a differential sense amplifier 126 comprising a first input 128, corresponding for example to the non-inverting input of the amplifier 126, coupled to the bit lines 110 of the memory elements 104 and a second input 130, corresponding for example to the inverting input of the amplifier 126, coupled to the bit line 118 of the read reference elements 114.

In the example of FIG. 1, the second input 130 of the amplifier 126 is coupled to the bit line 118 of the read reference elements 114 through the reference capacitor 122. As a variant, the output of the pulse generator 124 may be coupled to the plate line 120 of the read reference elements 114 through the reference capacitor 122. As another variant, the reference capacitor 122 may be formed by two separate capacitors, the second input 130 of the amplifier 126 being coupled to the bit line 118 of the read reference elements 114 through a first of these two capacitors, and the output of the pulse generator 124 being coupled to the plate line 120 of the read reference elements 114 through a second of the two capacitors.

According to a particular example embodiment, the reference capacitor 122 has a variable value. An example embodiment of such a variable-value reference capacitor 122 is illustrated in FIG. 2. In this example, the reference capacitor 122 comprises several switches 132, corresponding to transistors in the example of FIG. 2, and several fixed value capacitors 134, each coupled to one of the switches 132 configured to connect or not connect one of the fixed value capacitors 134 to conduction electrodes 136, 138 of the reference capacitor 122. In the example illustrated in FIG. 2, the conduction electrode 136 corresponds to the electrode that is coupled to the bit line 118 of the read reference elements 114 and the conduction electrode 138 corresponds to the electrode that is coupled to the second input 130 of the amplifier 126.

In the described example, the fixed value capacitors 134 have different values from one another. In the example illustrated in FIG. 2, the reference capacitor 122 comprises 32 fixed value capacitors 134 whose values are between 1 fF and 32 fF. Thus, by setting to the on state one of the switches 132 and by setting to the off state the other switches 132, it is possible to form, between the conduction electrodes 136, 138, a reference capacitor 122 whose value is between 1 fF and 32 fF. As a variant, it is possible for several of the switches 132 to be set to the on state simultaneously, depending on the desired value for the reference capacitor 122. The number of switches 132 and of fixed value capacitors 134 of the reference capacitor 122 may depend on the number of possible values desired for the reference capacitor 122. This number may differ from the example illustrated in FIG. 2.

Other alternative embodiments of the reference capacitor 122 are possible, using any type of element or component that allows the reference electrical capacitor 122 to be obtained or implemented.

Although not illustrated in the Figures, the memory device 100 further comprises, in this example, a control circuit configured to control the switches 132 according to a target or desired value of the reference capacitor 122. In FIG. 2, the control signals sent from this control circuit to the control electrodes of the switches 132, i.e. the gates of the transistors forming these switches 132 in this example, are called “Sel<0>”, “Sel<1>”, . . . , “Sel<31>”.

According to one embodiment, each of the fixed value capacitors 134 comprises at least two portions of electrically conductive material spaced apart from each other by one or more non-ferroelectric materials. For example, each of the fixed value capacitors 134 is of the Metal-Insulator-Metal (MIM) or Metal-Oxide-Metal (MOM) type or based on polysilicon or of the Metal-Oxide-Semiconductor (MOS) type, or corresponds to a backend, 2D or 3D, dielectric capacitor.

As a variant, the reference capacitor 122 may correspond to a single fixed value electrical capacitor, for example of the Metal-Insulator-Metal (MIM) or Metal-Oxide-Metal (MOM) type or based on polysilicon. In this case, the reference capacitor 122 does not comprise a switch 132.

Other example embodiments of the reference capacitor 122 are possible. In all cases, the reference capacitor 122 does not comprise the ferroelectric material of the ferroelectric capacitors 108 of the memory elements 104.

Whatever its structure, the value of the reference capacitor 122 is selected such that the value of the signal BL_{REF} obtained at the output of the reference capacitor 122 is between the values BL_{READ1} and BL_{READ0} obtained in the most unfavorable configuration, with BL_{READ1} corresponding to the value of the read signal expected when reading a memory element 104 in which a state “1” is stored and BL_{READ0} corresponding to the value of the read signal expected when reading a memory element 104 in which a state “0” is stored. The most unfavorable configuration corresponds to the most unfavorable statistical event tolerated by the structure, i.e. the set of unfavorable statistical coincidences that may comprise, for example, the most unfavorable case due to the process variations of the memory element 104 itself and/or of the selection transistor and/or of the PVT conditions of the environment and/or of the variation of each element, active or passive, playing a role in the circuit (multiplexer, sense amplifier, etc.). This most unfavorable configuration results in the production of a very bad state “1” being read and/or of a very bad state “0” being read, leading to the worst read window tolerated by the design margins of the circuit. When the value of the reference capacitor 122 is variable, the reference capacitor 122 can be configured such that its value can vary between the values BL_{READ1} and BL_{READ0} obtained in the most unfavorable configuration.

In the described example embodiment, the device 100 further comprises at least one multiplexer 140 for the lines of the memory elements 104 configured to couple the first input 128 of the amplifier 126 to at least one of the bit lines 110 of the memory elements 104 and to couple the output of the pulse generator 124 to one of the plate lines 112 of the memory elements 104. During an operation for reading one of the memory elements 104, the multiplexer 140 of the lines of the memory elements 104 is configured to couple the first input 128 of the amplifier 126 to the bit line 110 coupled to the memory element 104 being read and to couple the output of the pulse generator 124 to the plate line 112 coupled to the memory element 104 being read.

In addition, in the described example embodiment, the device 100 further comprises at least one multiplexer 142 of the lines of the read reference elements 114 configured to couple the second input 130 of the amplifier 126 to the bit line 118 of the read reference elements 114 (through the reference capacitor 122 in the described example) and to couple the output of the pulse generator 124 to the plate line 120 of the read reference elements 114. This multiplexer 142 has electrical characteristics similar to those of the multiplexer 140 so that the signals passing through the multiplexer 142 undergo the same modifications as those undergone by the signals passing through the multiplexer 140 and which are due to the multiplexers. In this example, the reference capacitor 122 is coupled to the reference bit line 118 through the multiplexer 142.

As a variant, the device 100 may not comprise the multiplexer 142.

In the described example embodiment, when reading one of the memory elements 104, a control signal is applied to the word line to which the memory element 104 to be read is coupled, causing the setting to the on state of the transistors 106 of the memory elements 104 of the line of the array 102 to which the memory element 104 to be read belongs as well as of the transistor 116 of the read reference element 114 belonging to that line. A read pulse is sent to the plate line 112 coupled to the memory element 104 to be read and to the plate line 120 of the read reference elements 114, from the pulse generator 124 and via the multiplexers 140, 142. As a variant, the read pulses sent on the plate line 112 coupled to the memory element 104 to be read and on the plate line 120 may correspond to separate pulses that can be generated separately. A read signal is obtained on the bit line 110 coupled to the memory element 104 being read that corresponds to the memory element 104 whose transistor 106 is in the on state and that receives the read pulse. This read signal is received on the first input 128 of the amplifier 126. In parallel with the reception of this read signal, a reference signal is obtained at the output of the reference capacitor 122 and is received on the second input 130 of the amplifier 126. A comparison of the read signal and of the reference signal, which correspond to voltages in the described example, is performed by the amplifier 126, which then outputs a signal whose value is representative of the value being read.

FIG. 3 schematically illustrates a read pulse, designated by the reference 200. In this Figure, the reference 202 designates the value BL_{READ1} theoretically expected for the read signal when reading a state “1” stored in the memory element 104 being read, the reference 204 designates the value BL_{READ0} theoretically expected for the read signal when reading a state “0” stored in the memory element 104 being read, the reference 206 designates the value BL_{REF} of the reference signal obtained at the output of the reference capacitor 122 and the reference 208 designates the read result signal obtained at the output of the amplifier 126 whose value depends on the comparison made between the read signal and the reference signal.

FIG. 4 schematically illustrates an example embodiment of a part of the memory device 100 according to the above described first embodiment.

In this Figure, the word lines coupled to the gates of the transistors 106 and 116 are designated by the reference 144 and the control circuit of the word lines is designated by the reference 146. In addition, the parasitic resistances and capacitances formed by the word lines, the bit lines 110, 118 and the plate lines 112, 120 are represented symbolically and designated by the reference 148. The read pulses sent on the plate lines 112, 120 are respectively called “PL_READ” and “PL_REF”. The read signal retrieved at the output of the multiplexer 140 is called “master_BLREAD” and the reference signal retrieved at the output of the multiplexer 142 is called “master_BLREF”.

In this example, the memory device 100 further comprises a differential multiplexer 150 configured to couple the first and second inputs 128, 130 of the amplifier 126 to the multiplexer 140 of the lines of the memory elements 104 and to the multiplexer 142 of the lines of the read reference elements 114. In this example, the differential multiplexer 150 allows to isolate the amplifier 126 from the lines on which the “master_BLREAD” and “master_BLREF” signals are retrieved, particularly during a writing to the array 102.

In this example, the memory device 100 also comprises, at the foot of the bit and plate lines, precharge transistors 149 used to predefine known and stable voltage values on the bit and plate lines, which allows to limit the risk of leakage current when the memory device 100 is at rest.

In this example, the reference capacitor 122 is coupled to the reference plate line 120 through the multiplexer 142.

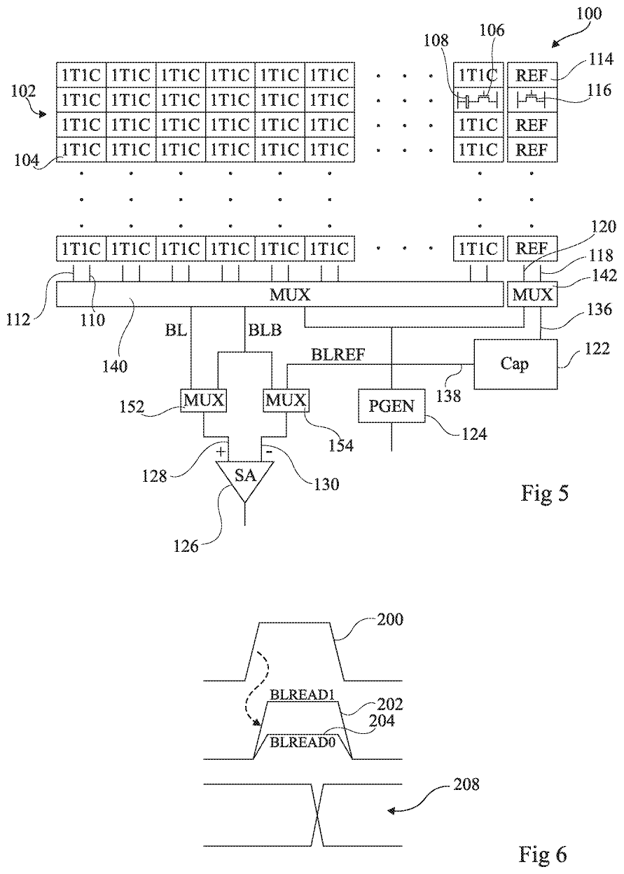

An example of a memory device 100 according to a second embodiment is described below in connection with FIG. 5.

Compared to the memory device 100 according to the first embodiment, the memory device 100 according to the second embodiment can operate in two different read modes. A first one of these two read modes corresponds to that implemented by the memory device 100 according to the first above described embodiment, in which a comparison is performed between the value BL_{REF} of the reference signal and that of the read signal delivered on the bit line 110 coupled to the memory element 104 being read. A second read mode of the memory device 100 according to the second embodiment corresponds to a differential read mode in which the amplifier 126 performs a comparison between the signal obtained on the bit line 110 of the memory element 104 being read and the complementary signal obtained on a complementary bit line coupled to the memory element 104 being read. In this second read mode, the reference signal is not used to determine the value of the memory element 104 being read. In this example, the reference capacitor 122 is coupled to the reference bit line 118 through the multiplexer 142.

In order to implement either of the two read modes, the memory device 100 according to the second embodiment comprises at least one multiplexer 152, referred to as a first differential multiplexer, configured to couple the first input 128 of the amplifier 126 to the bit line 110 (“BL” in FIG. 5) coupled to the memory element 104 being read or to the complementary bit line (“BLB” in FIG. 5) coupled to that memory element 104. In addition, the memory device 100 according to the second embodiment also comprises another multiplexer 154, referred to as a second differential multiplexer, configured to couple the second input 130 of the amplifier 126 to the complementary bit line coupled to the memory element 104 being read (when implementing the second read mode) or to the bit line 118 of the read reference elements 114 (when implementing the first embodiment).

In the first read mode, the signals obtained correspond to those previously described in connection with FIG. 3. The signals obtained by implementing the second read mode are illustrated in FIG. 6, in which complementary read signals (“BLREAD1” and “BLREAD0”) are compared to determine the state stored in the memory element 104 being read.

In general, the value of the signal BL is compared, using the amplifier 126, either with the value of the signal BL_{REF} in the first read mode or with the value of the signal BLB in the second read mode. Thus, when the value of the signal BL is greater than or equal to the compared value, the amplifier 126 outputs a logical “1” and when the value of the signal BL is strictly less than the compared value, the amplifier 126 outputs a logical “0”.

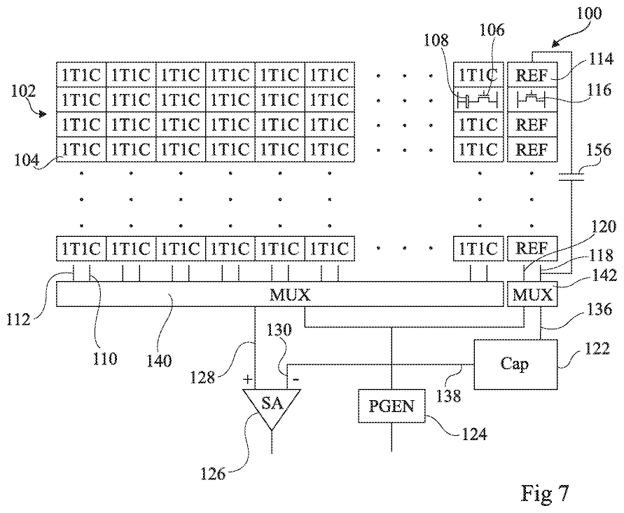

An example of a memory device 100 according to a variant of the first embodiment is described below in connection with FIG. 7.

Compared to the memory device 100 previously described in connection with FIG. 1, the memory device 100 comprises an additional capacitor 156 coupled in parallel to the bit line 118 of the read reference elements 114. The value of the additional capacitor 156 may be variable or not, but is preferably fixed. The additional capacitor 156 is, for example, of the same type as the reference capacitor 122 (MOM, MOS, etc.).

The additional capacitor 156 forms, with the reference capacitor 122 and the parasitic capacitances present on the bit line 118 and the plate line 120, a capacitive divider bridge. A variation in the value of the reference capacitor 122 varies the value of the ratio between the value of the additional capacitor 156 and that of the reference capacitor 112, which adjusts the value BL_{REF} of the reference signal being obtained.

The presence of the additional capacitor 156 between the transistors 116 of the read reference elements 114 and the conduction electrode 136 of the reference capacitor 122 allows the memory device 100 to get rid of the capacitive differences between the bit and plate lines 118, 120 of the reference branch and the bit and plate lines 110, 112 of the read branch while relaxing the design margins of the reference capacitor 122 to have accurate and stable capacitive elements in the reference capacitor 122, on the side of the amplifier 126. The addition of this additional capacitor 156 makes it easier, in particular, to adjust the value BL_{REF} of the reference signal in the middle of the reading window, between the values BL_{READ1} and BL_{READ0}.

This variant can be seen as equivalent to implementing a more precise variable reference capacitor 122, so as to have values between 1 fF and 32 fF, for example.

In this example, the reference capacitor 122 is coupled to the reference bit line 118 through the multiplexer 142.

According to one example embodiment, in an array 102 comprising columns each comprising 256 memory elements 104, the value of the additional capacitor 156 is, for example, equal to 32 fF and the value of the reference capacitor 122 is variable and equal to one of 32 possible values (selected by a 5-bit command). Considering the example embodiment of FIG. 2, the smallest fixed value of the capacitor 134 has, for example, a value equal to 8 fF. The value of the reference capacitor can take one of 32 values ranging from 8 fF to 256 fF. The selection of the value of the additional capacitor 156 makes it possible to determine what level of precision and what range of values can be achieved with elements that can be integrated into the memory device 100. Without this additional capacitor 156, the smallest fixed value of the capacitor must be equal to 2 fF in order to have 32 possible values in the desired range of values, which is more complex to achieve than a capacitor of a fixed value equal to 8 fF.

This variant can be applied to the second embodiment of the memory device 100.

In all embodiments and example embodiments, a mixed architecture, or circuit, for generating read references for a memory device comprising capacitive memory elements of the FeRAM type is provided. This architecture is referred to as “mixed” because it comprises the read reference elements 114 integrated into the array 102 and the reference capacitor 122 external to the array 102.

In the memory device 100, the read reference elements 114 allow to form a dummy bitline integrated into the array 102 and close to the bitline of the memory element 104 being read, allowing in particular the value of the read reference delivered to be structurally adjusted to the current/voltage variations sensitive to the spatial position of the memory element 104 being read in the array 102.

In the various examples, the arrangement of the read reference elements 114 in the array 102 of memory elements 104 does not mean that the reference elements 114 are arranged, with memory elements 104, in a same column. The reference bit and plate lines 118, 120 to which the read reference elements 114 are coupled are separate from the bit and plate lines 110, 112 to which the memory elements 104 are coupled.

In addition, the memory device 100 allows to implement a differential reading using a reference branch, with reduced cost in terms of surface area compared to the existing differential solutions of the 2T2C type.

Moreover, the read reference elements 114 do not comprise any ferroelectric capacitor and are therefore not subject to the variability associated with such capacitors. The obtained read reference is accurate, stable and not or only slightly sensitive to the local variations. In addition, the obtained read reference follows as closely as possible the variations in the memory elements to be read, takes into account the systematic variations induced by the structure of the array 102, such as, for example, the differences in parasitic resistances and capacitances related to the location of the memory element 104 being read in the array 102, requires only a small surface area and is also controllable and drivable thanks to the possible parameterization of the reference capacitor 122 that is external to the array 102 of memory elements 104.

The obtained read reference makes it possible to make a maximum use of the reading window provided by the FeRAM technology, which makes it possible, in the first instance, to optimize the yield and/or sacrifice a part of this read margin to increase the speed of the memory device 100, or reduce the surface area required for its implementation.

The value of the reference capacitor 122 can be parameterized to adjust the reading threshold of the amplifier 126 as closely as possible. Adjusting the value of the reference capacitor 122, for example by initially selecting the reference capacitor 122 when this capacitor has a fixed value or by parameterizing this value when this capacitor has a variable value, provides a significant reading margin. This adjustment can be made, for example, when initializing the memory device 100 before using it.

No capacitive element is added to the read reference elements 114, which allows not to create a variability in the measurement of the signals. Moreover, the absence of a capacitive element in each read reference element 114 avoids a considerable increase in the density and the size of the memory device 100. To achieve this, the reference capacitive element 122 is offset outside the array 102.

When the reference capacitor 122 comprises at least two portions of electrically conductive material spaced apart from each other by one or more non-ferroelectric materials, this allows to limit the fatigue (i.e. wear) and “imprint” phenomena of the reference capacitor 122. Actually, the ferroelectric capacitors are subject to the “imprint” phenomenon, which corresponds to the difficulty of writing a state in a ferroelectric capacitor that has long stored a state opposite to the one to be written. Moreover, the ferroelectric capacitors are subject to the fatigue phenomenon, which means that the more the number of write cycles in a ferroelectric capacitor increases, the more the value written in it is reduced. Thus, thanks to a reference capacitor having one or more non-ferroelectric materials, the risk of fatigue of the reference capacitor is greatly reduced and the “imprint” phenomenon is reduced, which allows to provide a robust memory device.

In the here provided description of the memory device 100, only the elements related to reading the memory elements 104 are described. However, the memory device 100 comprises other elements and/or circuits, not here described, dedicated to writing and erasing the memory elements 104.

1. A memory device comprising at least:
an array of memory elements in which each memory element comprises at least one transistor and at least one ferroelectric capacitor;
read reference elements, integrated into the array of memory elements, each comprising at least one transistor connected between a bit line and a plate line of the read reference elements ;
at least one reference capacitor external to the array of memory elements and coupled to the bit line and/or the plate line of the read reference elements;
a pulse generator whose at least one output is coupled to plate lines of the memory elements and to the plate line of the read reference elements; and
a differential sense amplifier comprising a first input coupled to bit lines of the memory elements and a second input coupled to the bit line of the read reference elements;
and wherein the read reference elements form a column of read reference elements coupled to the memory elements such that word lines are each coupled to gates of the transistors of the memory elements of a same line of the array and to a gate of the transistor of one of the read reference elements.

2. The memory device according to claim 1, wherein said at least one reference capacitor comprises at least two portions of electrically conductive material spaced apart from each other by one or more non-ferroelectric materials.

3. The memory device according to claim 2, wherein said at least one reference capacitor is of the Metal-Insulator-Metal or Metal-Oxide-Metal type, or based on polysilicon, or of the Metal-Oxide-Semiconductor type.

4. The memory device according to claim 1, wherein the second input of the differential sense amplifier is coupled to the bit line of the read reference elements through said at least one reference capacitor, and/or wherein the output of the pulse generator is coupled to the plate line of the read reference elements through said at least one reference capacitor.

5. The memory device according to claim 1, further comprising at least one multiplexer of the lines of the memory elements configured to couple the first input of the differential sense amplifier to at least one of the bit lines of the memory elements, and to couple the output of the pulse generator to one of the plate lines of the memory elements.

6. The memory device according to claim 1, further comprising at least one multiplexer of the lines of the read reference elements configured to couple the second input of the differential sense amplifier to the bit line of the read reference elements, and to couple the output of the pulse generator to the plate line of the read reference elements.

7. The memory device according to claim 6, further comprising at least:
a multiplexer of the lines of the memory elements configured to couple the first input of the differential sense amplifier to at least one of the bit lines of the memory elements, and to couple the output of the pulse generator to one of the plate lines of the memory elements,
at least one differential multiplexer configured to couple the first and second inputs of the differential sense amplifier to the multiplexer of the lines of the memory elements and to the multiplexer of the lines of the read reference elements.

8. The memory device according to claim 6, further comprising at least:
a multiplexer of the lines of the memory elements configured to couple the first input of the differential sense amplifier to at least one of the bit lines of the memory elements, and to couple the output of the pulse generator to one of the plate lines of the memory elements,
a first differential multiplexer configured to couple the first input of the differential sense amplifier to the bit line coupled to the memory element being read or to a complementary bit line coupled to the memory element being read, and
a second differential multiplexer configured to couple the second input of the differential sense amplifier to the complementary bit line coupled to the memory element being read or to the bit line of the read reference elements.

9. The memory device according to claim 1, wherein the reference capacitor has a variable value.

10. The memory device according to claim 9, wherein the reference capacitor comprises a plurality of switches and a plurality of fixed value capacitors each coupled to one of the switches configured to connect or not connect one of the fixed value capacitors to conduction electrodes of the reference capacitor.

11. The memory device according to claim 10, wherein the fixed value capacitors have values different from one another.

12. The memory device according to claim 10, further comprising a control circuit configured to control the switches according to a target value of the reference capacitor.

13. The memory device according to claim 1, wherein each of the memory elements is of the 1T1C type.

14. The memory device according to claim 1, further comprising an additional capacitor coupled in parallel to the bit line of the read reference elements.
